(19) United States
(12) Patent Application Publication
(10) Pub. No.: US 2014/0198528 A1
(43) Pub. Date: Jul. 17, 2014

(54) WAVELENGTH CONVERSION CHIP FOR A LIGHT EMITTING DIODE, AND METHOD FOR MANUFACTURING SAME

(71) Applicants: Yong Tae KIim, Suwon-si (KR); Tomio Inoue, Suwon-si (KR); Je Won Kim, Seoul (KR); Tsuyoshi Tsutsui, Suwon-si (KR); Jong Ho Lee, Seoul (KR); Seung Wan Chae, Yongin-si (KR)

(72) Inventors: Yong Tae KIim, Suwon-si (KR); Tomio Inoue, Suwon-si (KR); Je Won Kim, Seoul (KR); Tsuyoshi Tsutsui, Suwon-si (KR); Jong Ho Lee, Seoul (KR); Seung Wan Chae, Yongin-si (KR)

(73) Assignee: Samsung Electronics Co., Ltd., Suwon-si (KR)

(21) Appl. No.: 14/239,100

(22) PCT Filed: Aug. 17, 2011
(86) PCT No.: PCT/KR2011/006015

§ 371 Date: Feb. 14, 2014

(51) Int. Cl. H01L 33/50; F21V 8/00

(52) U.S. Cl. CPC H01L 33/50; G02B 6/0073
USPC 362/612; 438/27; 257/98

(57) ABSTRACT

There is provided a method of manufacturing a wavelength converted LED chip, including attaching a plurality of LED chips to a chip alignment region of an upper surface of a temporary support plate, forming a conductive bump on the electrode of the respective LED chips, forming a phosphor-containing resin encapsulation part in the chip alignment region to cover the conductive bump, polishing the phosphor containing resin encapsulation part, forming the wavelength converted LED chips by cutting the provided phosphor containing resin encapsulation part between the LED chips, the wavelength converted LED chip including a wavelength conversion layer obtained from the phosphor containing resin encapsulation part and formed on lateral surfaces and an upper surface of the wavelength converted LED chip, and removing the temporary support plate from the wavelength converted LED chip.

### TECHNICAL FIELD

Aspects of embodiments relate to a wavelength converted light emitting diode chip, and more particularly, to a wavelength converted light emitting diode chip reducing a color temperature deviation depending on a radial angle while embodying uniform light emission characteristics, and a method of manufacturing the same.

### BACKGROUND ART

Light emitting diodes (LEDs) are semiconductor devices converting electrical energy into light energy and are configured of a compound semiconductor emitting a specific wavelength of light based on an energy band gap. The use thereof has become widespread in apparatuses in the fields of displays such as optical communications and mobile displays, computer monitors, and the like, back light units (BTUs) to illumination devices.

In particular, in the development of LEDs for illumination devices, a relatively high level of current, a large amount of light, and uniform light emission characteristics are required, as compared to LEDs according to the related art. Thus, the development of novel designs and processes are required.

According to the related art, white light emitting device packages have been manufactured by applying a mixture of a phosphor and a transparent resin to the vicinity of LED chips through a publicly disclosed method such as a dispensing method or the like. In this case, the amounts of phosphors located on upper surfaces and lateral surfaces of LED chips are different from each other, such that a difference in color characteristics such as color temperatures between white light emitted from chip upper surfaces and white light emitted from chip lateral surfaces may occur.

In addition, regions in which LED chips are mounted are formed to have a cup-shaped structure, and when the cup-shaped structures are filled with a resin, optical paths are increased due to scattering of light due to phosphors and light efficiency is also deteriorated.

On the other hand, even in a case in which phosphor layers are directly formed on the wafer level, under the same conditions, it may be difficult to secure uniform light emission characteristics.

In detail, even when semiconductor epitaxial layers are grown under the same growth conditions on a single wafer, different light emission characteristics may be provided depending on respective chip regions.

Therefore, when the same phosphor layer is applied thereto, since consequently obtained white LED chips have different white light characteristics, according to respective chips, due to different light emission characteristics, color scattering may be problematic.

### DISCLOSURE

### Technical Problem

An aspect of an embodiment may provide a method of manufacturing a wavelength converted LED chip having a phosphor layer, capable of providing white light corresponding to a required color coordinate region while having a uniformly coated chip surface.

### Technical Solution

According to an aspect of an embodiment, a method of manufacturing a wavelength converted light emitting diode (LED) chip may include: attaching a plurality of LED chips to a chip alignment region of an upper surface of a temporary support plate such that a surface thereof on which at least one electrode is formed is directed in an upper direction; forming a conductive bump on the electrode of the respective LED chips; forming a phosphor containing resin encapsulation part in the chip alignment region so as to cover the conductive bump; polishing the phosphor containing resin encapsulation part; forming the wavelength converted LED chips by cutting the provided phosphor containing resin encapsulation part between the LED chips, the wavelength converted LED chip including a wavelength conversion layer obtained from the phosphor containing resin encapsulation part and formed on lateral surfaces and an upper surface of the wavelength converted LED chip; and removing the temporary support plate from the wavelength converted LED chip.

The plurality of LED chips among LED chips obtained in at least one wafer may be selected by a criterion of specific emitted light characteristics. Here, the emitted light characteristics may be at least one of a peak wavelength of emitted light and an output of light.

The temporary support plate may include a dam structure encompassing the chip alignment region. In this case, the dam structure may have a height at least greater than that of a chip including the conductive bumps formed therein.

A distance between the LED chips attached to the temporary support substrate may be greater than a distance twice a thickness of a portion of a light wavelength conversion layer to be located on lateral surfaces of the LED chip.

The forming of the phosphor containing resin encapsulation part may be performed through a process selected from a dispensing method, a screen printing method, a spin coating method, a spray coating method and a transfer molding method.

The plurality of LED chips may include an insulating substrate, a semiconductor epitaxial layer including a first conductive semiconductor layer, an active layer and a second conductive semiconductor layer sequentially formed on the insulating substrate, and first and second electrodes respectively formed on the first and second conductive semiconductor layers.

The plurality of LED chips may include a conductive substrate, a semiconductor epitaxial layer including a first conductive semiconductor layer, an active layer and a second conductive semiconductor layer sequentially formed on the conductive substrate, and an electrode formed on the second conductive semiconductor layer.

According to an aspect of an embodiment, a wavelength converted LED chip may include: a substrate; a semiconductor epitaxial layer including a in conductive semiconductor layer, an active layer and a second conductive semiconductor layer sequentially formed on the substrate; at least one electrode formed on the semiconductor epitaxial layer; a conductive bump formed on a surface of the at least one electrode; and a wavelength conversion layer formed to encompass lateral surfaces of the substrate together with the semiconductor epitaxial layer, including a resin containing at least one type of phosphor powder, and having an upper surface formed to have the same level of plane as that of an upper surface of the conductive bump.

The substrate may be an insulating substrate, and the at least one electrode may include first and second electrodes respectively formed on the first and second conductive semi conductor layers.

The substrate may be a conductive substrate, and the at least one electrode may include an electrode formed on the second conductive semiconductor layer.

### Advantageous Effects

According to an embodiment of the inventive concept, when a phosphor layer is formed on a chip level, a majority of chip surfaces, including lateral surfaces as well as an upper surface, may be covered with a phosphor layer such that a phosphor layer formation technology of improving color scattering yield and significantly reducing color temperature deviation per angle of beam spread may be provided.

In detail, LED chips may be classified in terms of at least one of wavelength of light and output of light in advance, in consideration of formation of a phosphor layer, such that a phosphor may be uniformly coated according to light characteristics of LED chips, and thus a high quality white LED chip having a required target color coordinate region may be provided. Accordingly, mass production may be improved through improved process yield and reduced manufacturing costs

### DESCRIPTION OF DRAWINGS

The above and other aspects, features and other advantages will be more clearly understood from the following detailed description taken in conjunction with the accompanying drawings, in which:

FIGS. 1A to 1F are cross-sectional views illustrating respective manufacturing processes of an LED chip according to an embodiment of the inventive concept;

FIG. 2 is a side cross-sectional view of an LED chip according to an embodiment of the inventive concept;

FIG. 3 is an upper plan view of a temporary support plate to which LED chips are attached according to an embodiment of the inventive concept;

FIG. 4 is a side cross-sectional view of a wavelength converted LED chip according to an embodiment of the inventive concept;

FIG. 5 is a side cross-sectional view of a wavelength converted LED chip according to another embodiment of the inventive concept;

FIGS. 6A and 6B are cross-sectional views illustrating a backlight unit according to various embodiments; and

FIG. 7 is an exploded perspective view of a display device according to an embodiment of the inventive concept.

### BEST MODE FOR INVENTION

Hereinafter, embodiments will be described in detail with reference to the accompanying drawings.

Embodiments may, however, be embodied in many different forms and should not be construed as being limited to embodiments set forth herein. Rather, these embodiments are provided so that this disclosure will be thorough and complete, and will fully convey the scope of the inventive concept to those skilled in the art. In the drawings, the shapes and dimensions of elements may be exaggerated for clarity.

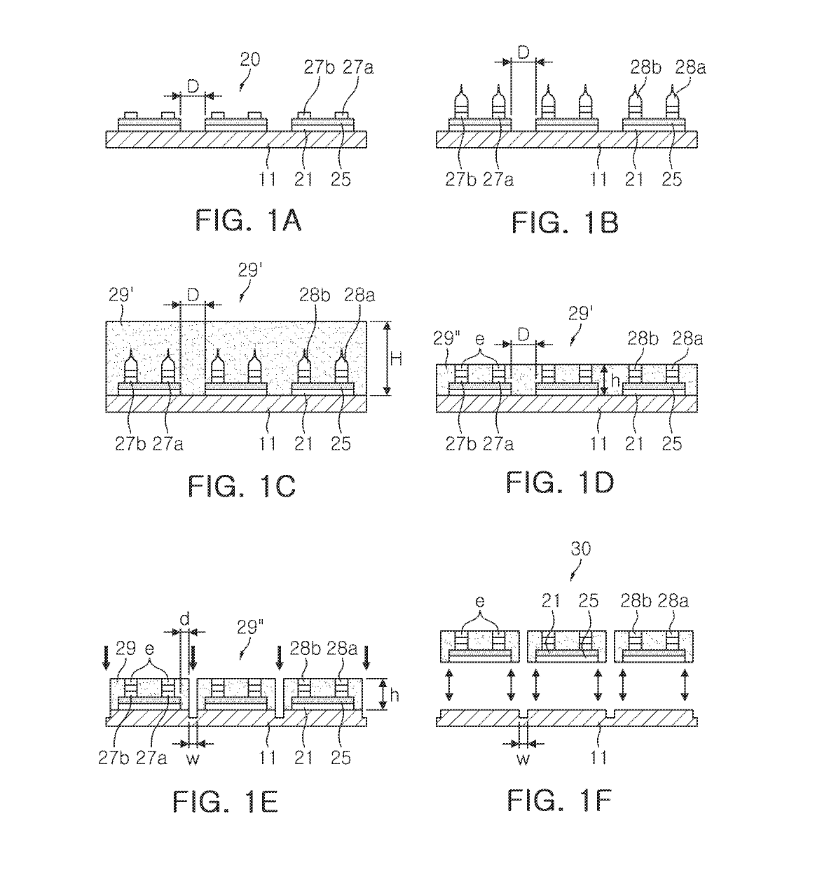

FIGS. 1A to 1F are cross-sectional views illustrating respective processes of manufacturing a light emitting diode (LED) chip according to an embodiment of the inventive concept.

In an LED chip manufacturing process according to an embodiment, first, a plurality of LED chips 20 may be attached to a chip alignment region of an upper surface of a temporary support plate 11.

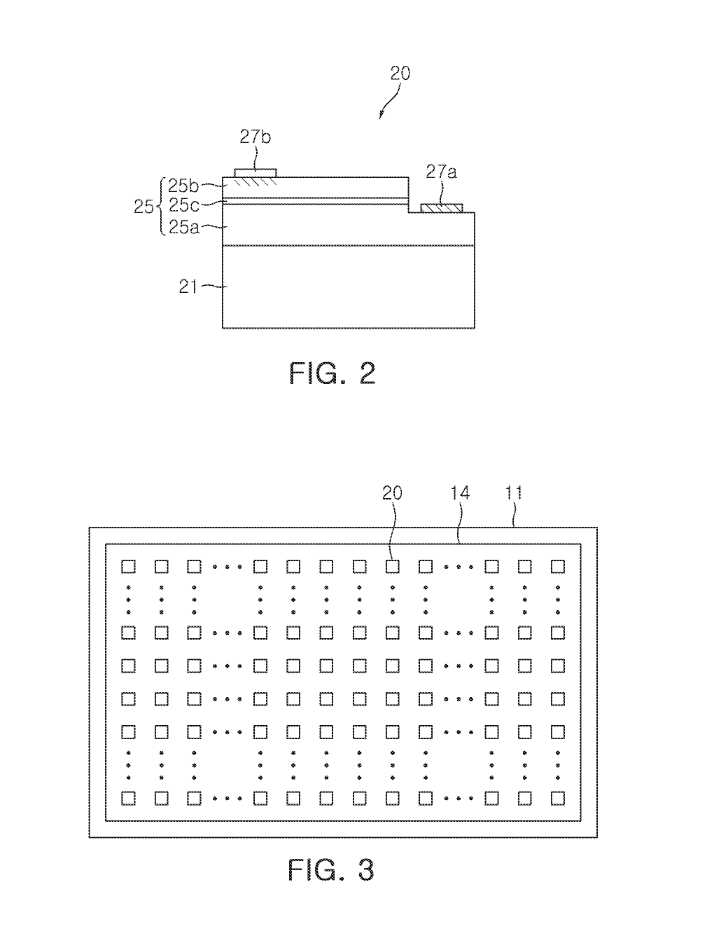

The plurality of LED chips 20 may have a structure as illustrated in FIG. 2. That is, the LED chip 20 employed according to the present embodiment may include a semiconductor epitaxial layer 25 formed by stacking a first conductive semiconductor layer 25a, an active layer 25c and a second conductive semiconductor layer 25b on an insulating substrate 21. In addition, first and second electrodes 27a and 27b may be formed on mesa etched, exposed regions of the first conductive semiconductor layer 25a and the second conductive semiconductor layer 25b, respectively.

As such, when the first and second electrodes 27a and 27b having different polarities are both located in a direction in which the semiconductor epitaxial layer 25 is formed, the plurality of LED chips may be attached to the temporary support plate such that a surface on which the two electrodes 27a and 27b are formed is directed in an upper direction thereof.

Unlike the description above, when, after being formed on a conductive substrate, a further polar electrode is located on a surface opposite thereto (it is generally referred to as a “vertical structural light emitting device”), a surface having an electrode formed thereon and having a conductive bump to be formed thereon may be formed toward an upper part thereof.

The plurality of LED chips 20 may be selected by criterion of specific emitted light characteristics among a plurality of LED chips in at least one wafer. Here, the emitted light characteristics may be at least one of a peak wavelength of emitted light and an output of light.

In general, chips obtained from a single wafer may also represent different wavelength characteristics of light. Thus, when a phosphor layer is applied to the entire chip regions in a lump on a wafer level, there may occur a deviation in a converted wavelength of light, for example, white light characteristics, such that a plurality of chips may not satisfy a required target color coordinate region.

However, in the present embodiment, since a phosphor layer formation process is performed on a chip level, chips may be classified as chips similar to each other in terms of wavelength characteristics of light in advance, such that a phosphor layer appropriate to obtain required color coordinate characteristics may be applied thereto. Therefore, in a wafer level process, a relatively high quality wavelength converted LED chip corresponding to a target color coordinate region may be obtained.

The temporary support plate 11 may be formed of a material facilitating the separation of an LED chip having a phosphor layer formed therein, performed after the phosphor layer is formed, or a material having excellent thermal characteristics. For example, the temporary support plate 11 may be an ultraviolet (UV) curable polyethyleneterephtalate (PET) film having relatively high heat resistance, a metal substrate formed of a metal such as aluminum (Al) or copper (copper) having excellent heat conductivity, or a substrate formed of an inorganic material such as silicon. However, the inventive concept should not be considered as being limited thereto.

As illustrated in FIG. 1A, a distance D between the LED chips 20 attached to the temporary support substrate 11 may be set to be greater than a distance twice a thickness (“d” of FIG. 1E) of a portion of a wavelength conversion layer 29 to be located on a lateral surface of the LED chip 20. For example, the distance D may be sec in consideration of a slicing width to be removed in a cutting process of FIG. 1E.

For example, the temporary support plate 11 may include a dam structure 14 encompassing the chip alignment region as shown in FIG. 2. As shown in FIG. 2, the LED chips 20 attached to the chip alignment region may have an M×N array so as to allow a uniform distance to be maintained therebetween.

The dam structure 14 may have a height at least greater than that of a chip including the conductive bumps formed therein, such that a phosphor layer to be formed may cover the conductive bumps 28a and 28b as illustrated in FIG. 1C.

Subsequently, as illustrated in FIG. 1B, the conductive bumps 28a and 28b may be formed on the electrodes 27a and 27b of the respective LED chips 20.

The conductive bumps 28a and 28b may be formed to have a height greater than a required thickness of the phosphor layer to be formed on a surface thereof. For example, the conductive bumps 28a and 28b may be formed to have a thickness of 50 to 120 μm. In order to form a bump having such a great height, stud bumps may be stacked in two or more stages.

Then, as illustrated in. FIG. 1C, a resin encapsulation part 29′ in which a phosphor is contained in the chip alignment region may be formed.

The phosphor containing resin encapsulation part 29′ formed in the present process may be formed to have a height H covering the conductive bumps 28a and 28b.

A process of forming the phosphor containing resin encapsulation part may be performed through a process selected from a dispensing method, a screen printing method, a spin coating method, a spray coating method and a transfer molding method. When a liquefied resin is applied thereto through the dispensing-like method, among the methods above, a formation height thereof may be determined depending on the dam structure.

Subsequently, as illustrated in FIG. 1D, the phosphor containing resin encapsulation part 29′ may be polished to expose the conductive bumps 28a and 28b to an upper surface thereof.

Through the present process, a thickness of the resin encapsulation part 29′ may be adjusted as necessary in the entire region while having a uniform thickness with respect to the overall chip. In addition, bonding regions e of the conductive bumps 28a and 28b may be exposed to an upper surface of the resin encapsulation part 29′.

Next, as illustrated in FIGS. 1E and 1F, wavelength converted LED chips 30 may be formed by cutting the phosphor containing resin encapsulation part 29′ formed between the LED chips and the wavelength converted LED chips 30 may be separated from the temporary support substrate 11.

The wavelength converted LED chip 30 obtained in the present process may include a wavelength conversion layer 29 obtained from the phosphor containing resin encapsulation part and formed on a lateral surface and an upper surface thereof.

In the case of the wavelength conversion layer 29 provided in the wavelength converted LED chip, a thickness h of a portion thereof formed on an upper surface of the chip may be precisely adjusted to have an appropriate thickness through a polishing process, and a thickness d thereof located on a lateral surface of the chip may be formed to have a precise and uniform thickness by setting the distance D and a slicing width w so as to be suitable therefor at the time of attaching the LED chips 20.

As such, by providing the wavelength conversion layer to have a uniform thickness on a majority of chip surfaces, including the chip lateral surfaces as well as the chip upper surface, color scattering yield may be improved and a color temperature deviation per angle of beam spread may be significantly reduced. In detail, on a chip level, LED chips may be classified in terms of at least one of wavelength of light and output of light in advance, in consideration of formation of a phosphor layer, such that the wavelength conversion layer may be provided no be suitable for light characteristics of LED chips to provide a high quality white LED chip having a required target color coordinate region.

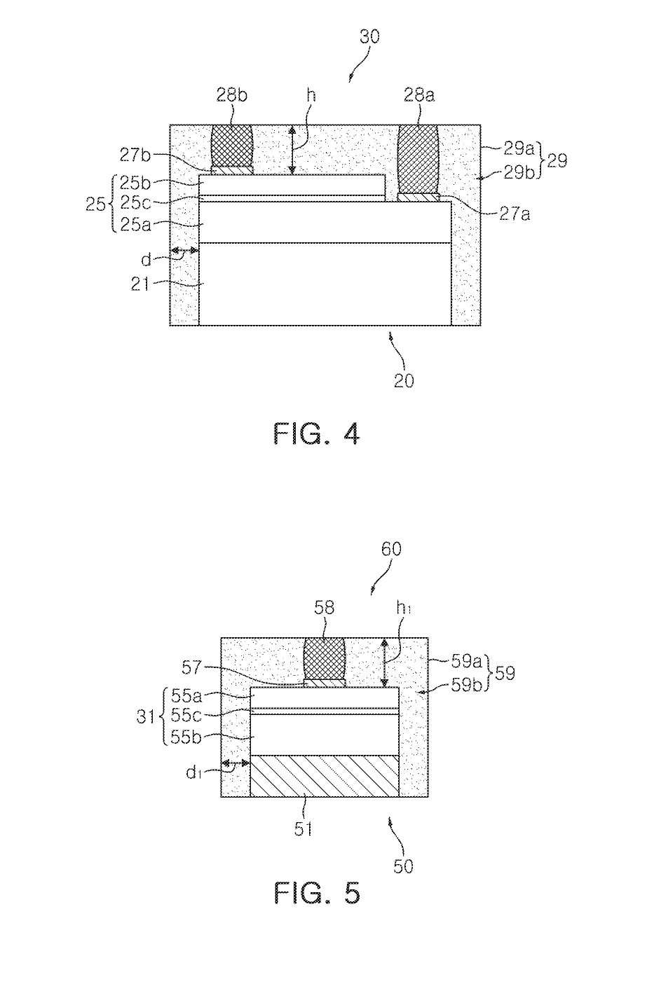

FIG. 4 is a side cross-sectional view of a wavelength converted LED chip obtained through the process illustrated in FIG. 1 according to an embodiment of the inventive concept.

The wavelength converted LED chip 30 shown in FIG. 4 may include a substrate 21 and a semiconductor epitaxial layer 25 including a first conductive semiconductor layer 25a, an active layer 25c and a second conductive semiconductor layer 25b sequentially formed on the substrate 21.

The substrate 21 may be an insulating substrate such as a sapphire substrate. In order to form a conducting electrode on the first conductive semiconductor layer 25a, an exposed region may be formed through mesa etching and a first electrode 27a may be formed on the exposed region of the first conductive semiconductor layer 25a. A second electrode 27b may be formed on the second conductive semiconductor layer 25b. The electrodes 27a and 27b of two polarities are both located toward a single surface.

The conductive bumps 28a and 28b may be formed on surfaces of the first and second electrodes 27a and 27b, respectively. In addition, the wavelength conversion layer 29 formed of a resin body 29b containing at least one type of phosphor powder 29a may be formed. The wavelength conversion layer 29 may be formed to encompass surfaces of the semiconductor epitaxial layer 25 and lateral surfaces of the substrate 21.

The wavelength conversion layer 29 may have an overall flat upper surface so as to have a uniform thickness h on an upper surface region of the chip 20, and the conductive bumps 28a and 28b may have a bonding region having the same level of plane as that of an upper surface of the wavelength conversion layer 29. Further, the wavelength conversion layer 29 may have a predetermined thickness d upwardly from a lateral surface of the chip 20.

As described above, in the wavelength converted LED chip according to the present embodiment, the wavelength conversion layer 29 may have an overall uniform thickness and the thickness thereof may be precisely controlled, such that a color temperature difference depending on a radial angle may be significantly reduced.

FIG. 5 is a side cross-sectional view of a light wavelength converted LED chip according to another embodiment of the inventive concept.

A wavelength converted LED chip 60 shown in FIG. 5 may include a substrate 51 and a semiconductor epitaxial layer 55 including a first conductive semiconductor layer 55a, an active layer 55c and a second conductive semiconductor layer 55b sequentially formed on the substrate 51.

The substrate 51 may be a conductive substrate such as a metal layer formed by plating. In this case, the electrode conducting with the first conductive semiconductor layer 55a may be provided through the substrate 51. On the other hand, an electrode 57 may be formed on an exposed region of the first conductive semiconductor layer 55a. A conductive bump 58 may be formed on a surface of the electrode 57. In addition, a wavelength conversion layer 59 formed of a resin body 59b containing at least one type of phosphor powder 59a may be formed.

The wavelength conversion layer 59 may be formed to encompass surfaces of the semiconductor epitaxial layer 55 and lateral surfaces of the substrate 51. The wavelength conversion layer 59 may have an overall flat upper surface so as to have a uniform thickness h1 on an upper surface region of the chip 50, and the conductive bump 58 may have a bonding region having the same level of plane as that of an upper surface of the wavelength conversion layer 59. Further, the wavelength conversion layer 59 may have a predetermined thickness d1 from a lateral surface of the chip 50.

In the wavelength converted LED chip 60 according, to the present embodiment (a vertically structured semiconductor light emitting device), similar to the case of FIG. 4, the wavelength conversion layer 59 may also have an overall uniform thickness, and a thickness thereof may be precisely adjusted, such that a color temperature difference depending on a radial angle may be significantly reduced. As such, a phosphor layer formation technology according to an embodiment of the inventive concept may be usefully applied to light emitting diodes of various structures.

LED chips having the above-mentioned wavelength conversion layer may be implemented as packages having various types of connection structure for ease of connection to an external circuit so as to be used as LED light sources of various apparatuses.

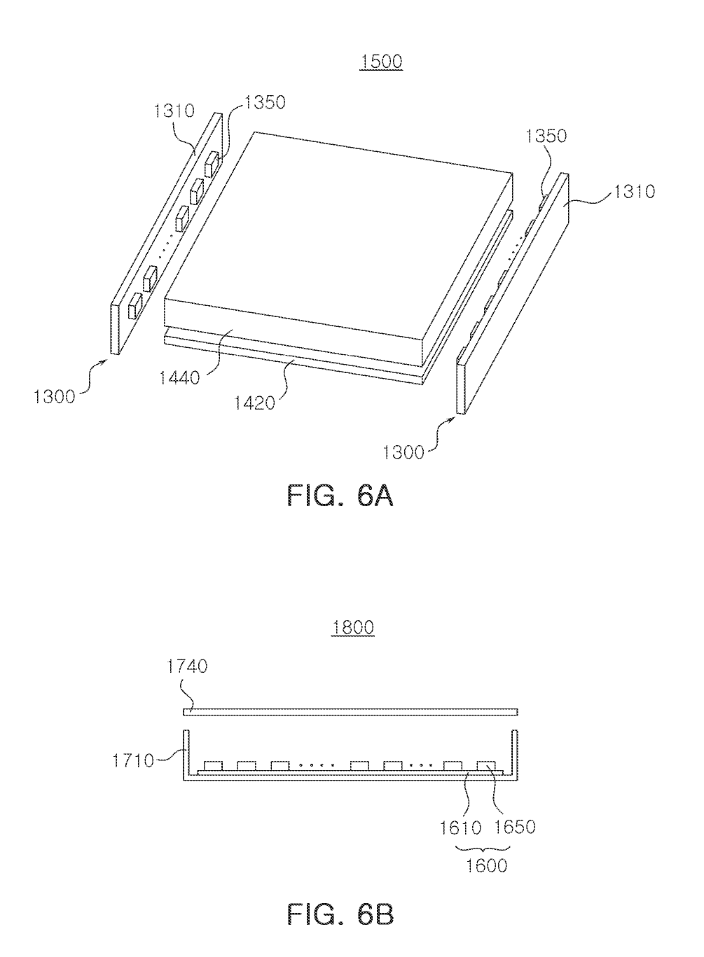

FIGS. 6A and 6B are cross-sectional views illustrating an example of a backlight unit according to various embodiments.

With reference to FIG. 6A, an edge-type backlight unit 1300 is illustrated as an example of a backlight unit in which a light emitting diode package according to an embodiment may be used as a light source.

The edge-type backlight unit 1300 according to the present embodiment may include a light guide plate 1340 and LED light source modules 1310 provided on both sides of the light, guide plate 1340.

Although the present embodiment illustrates the example in which the LED light source modules 1310 are provided on both opposing sides of the light guide plate 1340, the LED light source module may only be disposed on a single side thereof, and unlike the description above, additional LED light source modules may also be provided on other sides.

As illustrated in FIG. 6A, a reflective plate 1320 may be further provided on a lower part of the light guide plate 1340. The LED light source module 1310 used in the present embodiment may include a printed circuit board 1301 and a plurality of LED light sources 1350 mounted on the board 1301, and the LED light sources 1350 may be provided as a light emitting device package employing the wavelength converted LED chip.

With reference to FIG. 6B, a direct-type backlight unit 1400 is provided.

The direct-type backlight unit 1400 according to the present embodiment may include alight diffusion plate 1440 and LED light source modules 1410 arrayed on a lower surface of the light diffusion plate 1440.

The backlight unit 1400 illustrated in FIG. 6B may include a bottom case 1460 provided with a lower part of the light diffusion plate 1440 and receiving the light source modules.

The LED light source module 1410 employed in the present embodiment may include the printed circuit board 1401 and the plurality of LED light sources 1405 mounted on an upper surface of the printed circuit board 1401. The plurality of LED light sources 1405 may be used as light emitting device packages employing the above-mentioned wavelength converted LED chip therein.

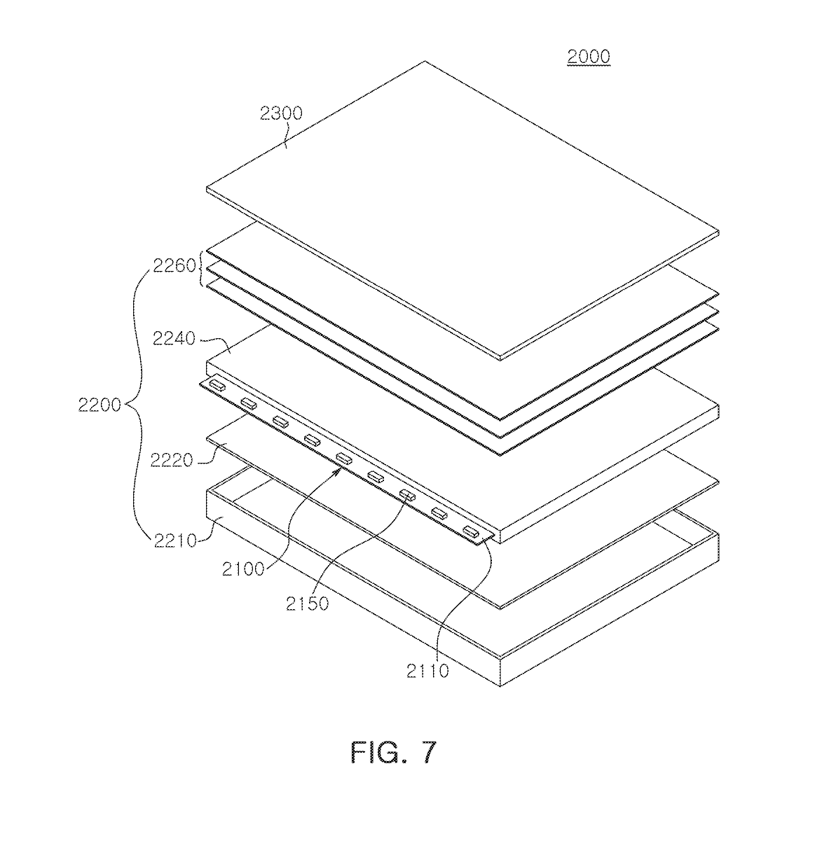

FIG. 7 is an exploded perspective view of a display device according to an embodiment of the inventive concept.

The display device 2400 shown in FIG. 7 may include a backlight unit 2200 and an image display panel 2300 such as a liquid crystal panel. The backlight unit 2200 may include a light guide plate 2240 and an LED light source module 2100 provided on at least one side of the light guide plate 2240.

In the present embodiment, the backlight unit 2200 may further include a bottom case 2210 and a reflective plate 2220 disposed below the light guide plate 2120 as shown in FIG. 7.

In addition, according to the requirements for various optical characteristics, the display device may include several types of optical sheets 2260 such as a diffusion sheet, a prism sheet or a protective sheet between the light guide plate 2240 and the liquid crystal panel 2300.

The LED light source module 2100 may include a printed circuit board 2110 provided with at least one side of the light guide plate 2240 and a plurality of LED light sources 2150 mounted on the printed circuit substrate 2110 to allow light to be incident onto the light guide plate 2240. The plurality of LED light sources 2150 may be light emitting device packages including the above-mentioned wavelength converted LED chip. The plurality of LED light sources employed in the present embodiment may be side view-type light emitting device packages of which sides adjacent to a light emission surface are mounted.

As described above, the above-mentioned phosphor may be applied to a package having various mounting structures to be applied to an LED light source module providing various types of white light. The above-mentioned light emitting device package or the above-mentioned light source module including the same may be applied to various types of display devices or illumination apparatuses.

While the inventive concept has been shown and described in connection with the embodiments, it will be apparent to those skilled in the art that modifications and variations can be made without departing from the spirit and scope of the inventive concept as defined by the appended claims.

1. A method of manufacturing a wavelength converted light emitting diode (LED) chip, comprising:
attaching a plurality of LED chips to a chip alignment region of an upper surface of a temporary support plate such that a surface thereof on which at least one electrode is formed is directed in an upper direction;
forming a conductive bump on the electrode of the respective LED chips;
forming a phosphor-containing resin encapsulation part in the chip alignment region so as to cover the conductive bump;
polishing the phosphor containing resin encapsulation part;
forming the wavelength converted LED chips by cutting the provided phosphor containing resin encapsulation part between the LED chips, the wavelength converted LED chip including a wavelength conversion layer obtained from the phosphor containing resin encapsulation part and formed on lateral surfaces and an upper surface of the wavelength converted LED chip; and
removing the temporary support plate from the wavelength converted LED chip.

2. The method of claim 1, wherein the plurality of LED chips are obtained from at least one wafer and selected by a criterion of specific emitted light characteristics.

3. The method of claim 2, wherein the emitted light characteristics are at least one of a peak wavelength of emitted light and an output of light.

4. The method of claim 1, wherein the temporary support plate includes a dam structure encompassing the chip alignment region.

5. The method of claim 4, wherein the dam structure has a height at least greater than that of a chip including the conductive bumps formed therein.

6. The method of claim 1, wherein a distance between the LED chips attached to the temporary support substrate is greater than a distance twice a thickness of a portion of a light wavelength conversion layer to be located on lateral surfaces of the LED chip.

7. The method of claim 1, wherein the temporary support plate is an ultraviolet (UV) curable polyethyleneterephtalate (PET) film.

8. The method of claim 1, wherein the forming of the phosphor containing resin encapsulation part is performed through a process selected from a dispensing method, a screen printing method, a spin coating method, a spray coating method and a transfer molding method.

9. The method of claim 1, wherein the plurality of LED chips include an insulating substrate, a semiconductor epitaxial layer including a first conductive semiconductor layer, an active layer and a second conductive semiconductor layer sequentially formed on the insulating substrate, and first and second electrodes respectively formed on the first and second conductive semiconductor layers.

10. The method of claim 1, wherein the plurality of LED chips include a conductive substrate, a semiconductor epitaxial layer including a first conductive semiconductor layer, an active layer and a second conductive semiconductor layer sequentially formed on the conductive substrate, and an electrode formed on the second conductive semiconductor layer.

11.-13. (canceled)

14. A light emitting device package comprising the wavelength converted LED chip manufactured through the method of claim 1.

15. A surface light source device comprising:
a light guide plate; and
an LED light source module formed on at least one side of the light guide plate to provide light to an inside of the light guide plate,
wherein the LED light source module includes a circuit board and an LED light source mounted on the circuit board and having the wavelength converted LED chip manufactured through the method of claim 1.

16. A display device comprising:
an image display panel providing an image; and
a backlight unit including the surface light source device of claim 15 providing light to the image display panel.

17. An illumination device comprising:
an LED light source module; and
a diffusion sheet formed on the LED light source module and allowing light incident from the LED light source module to be uniformly diffused thereon,
wherein the LED light source module includes a circuit board and an LED light source mounted on the circuit board and having the wavelength converted LED chip manufactured through the method of claim 1.
